(19) United States
(12) Patent Application Publication
(10) Pub. No.: US 2024/0395955 A1
(43) Pub. Date: Nov. 28, 2024

(54) Photosensitive Element and Assembly Method Thereof

(71) Applicant: First Sensor AG, Berlin (DE)

(72) Inventors: Iman Sabri Alirezaei, Berlin (DE); Martin Wilke, Berlin (DE); Ruben Chavez, Berlin (DE); Marc Schillgalies, Berlin (DE)

(73) Assignee: First Sensor AG, Berlin (DE)

(21) Appl. No.: 18/673,565

(22) Filed: May 24, 2024

(30) Foreign Application Priority Data
May 24, 2023 (EP) 23175174.4

(51) Int. Cl. H01L 31/0352; H01L 31/0224; H01L 31/0232; H01L 31/028; H01L 31/107; H01L 31/18

(52) U.S. Cl. CPC H01L 31/035254; H01L 31/022408; H01L 31/02327; H01L 31/028; H01L 31/107; H01L 31/1804

(57) ABSTRACT

A photosensitive element includes a semiconductor substrate, a first contact region connected to a first contact, and a second contact region connected to a second contact. The semiconductor substrate has a radiation receiving area through which an incident radiation can enter the photosensitive element and a radiation reflecting area disposed on a side of the semiconductor substrate opposite the radiation receiving area. A multiplication region multiplying a plurality of charges generated from the incident radiation is formed at the first contact region when a voltage is applied between the first contact and the second contact. The first contact and the second contact are arranged on the side of the semiconductor substrate opposite the radiation receiving area.

### CROSS-REFERENCE TO RELATED APPLICATIONS

This application claims the benefit of the filing date under 35 U.S.C. § 119 (a)-(d) of European Patent Application No. 23175174.4, filed on May 24, 2023.

### FIELD OF THE INVENTION

The present disclosure relates to a photosensitive element and an assembly method providing the photosensitive element.

### BACKGROUND

Photosensitive elements such as photodiodes are widely used to convert radiation into electrical signals. Thereby, the radiation enters the photodiode, is absorbed and a current is produced.

Such photosensitive elements are known in the field of safety devices for industrial automation and automotive applications. In particular, LIDAR (light detection and ranging) technology will be used in advanced driver-assistance systems (ADAS) and is the key technology for enabling autonomous driving. In these LIDAR systems, there are different detector styles used which are based on different photosensitive elements. One type of photosensitive elements are avalanche photodiodes (APDs).

APDs are semiconductor elements, which may be based on silicon and have a very compact size, high quantum efficiency and relatively high gain. The internal structure of an APD is made of an intrinsic or lightly doped p-type semiconductor, with heavily doped p and n-type regions that are in contact with the cathode and the anode. By using a highly doped region and a deep lightly doped region in silicon crystal, a very high internal field is maintained across the p-n-junction which produces a high internal gain. Through these metal contacts, an external high reverse bias voltage is supplied. When radiation enters the APD, the high internal field causes the avalanche effect of multiplying generated electron-hole pairs and causing an electrical signal at the output.

Common APD are fabricated using a complementary metal-oxide-semiconductor (CMOS) process with a p-doped epi-layer arranged over a highly doped p-type substrate. The anode is connected to the highly doped p-type substrate and on the opposite side of the APD the cathode is arranged. In operation, the radiation enters the APD at the cathode's side (front side) and the internal structure of the APD causes a flow of generated charges between the cathode and the anode. These APDs are wire-bonded to a corresponding carrier.

Such a CMOS fabricated single-photon avalanche diode (SPAD) is proposed by G. Paternoster et al. in their contribution to the 16th (Virtual) Trento workshop on Advanced Silicon Radiation Detects held on Feb. 16-18, 2021 (https://indico.cern.ch/event/983068/contributions/4223039/attachments/2191308/3703680/TRE DI21_Paternoster.pdf-retrieved on Mar. 2, 2023). Therein, a backside illuminated SPAD is proposed, which has one metal contact (cathode) arranged on the top side of the SPAD and another metal contact (anode) arranged on the bottom side of the SPAD. Radiation enters the SPAD from the bottom side. The charge that is generated in silicon flows vertically through the SPAD between the anode and the cathode.

One drawback of the current solutions is that the sensitivity and fill factor of the front-side illuminated APD is limited due to the wire-bonding of the APD. Further, due to the thick epi-layer for near infrared spectral range a trade-off between the requirements on the sensitivity and the speed of the APD has to be found.

### SUMMARY

A photosensitive element includes a semiconductor substrate, a first contact region connected to a first contact, and a second contact region connected to a second contact. The semiconductor substrate has a radiation receiving area through which an incident radiation can enter the photosensitive element and a radiation reflecting area disposed on a side of the semiconductor substrate opposite the radiation receiving area. A multiplication region multiplying a plurality of charges generated from the incident radiation is formed at the first contact region when a voltage is applied between the first contact and the second contact. The first contact and the second contact are arranged on the side of the semiconductor substrate opposite the radiation receiving area.

### BRIEF DESCRIPTION OF THE DRAWINGS

Features of the present invention will become more apparent by describing in detail exemplary embodiments thereof with reference to the accompanying drawings, in which:

FIG. 1 is a schematic sectional side view of a photosensitive element according to the present disclosure;

FIG. 2 is a schematic sectional top view of a layout of the photosensitive element according to the present disclosure; and

FIG. 3 is a schematic sectional side view of an assembled photosensitive element according to the present disclosure.

### DETAILED DESCRIPTION OF THE EMBODIMENTS

To better understand the present disclosure, it is explained in greater detail using the example depicted in the following Figures. Identical parts are hereby provided with identical reference numbers and identical component names. Furthermore, some features or combinations of features from the various examples shown and described may also represent independent solutions, inventive solutions or solutions according to the disclosure.

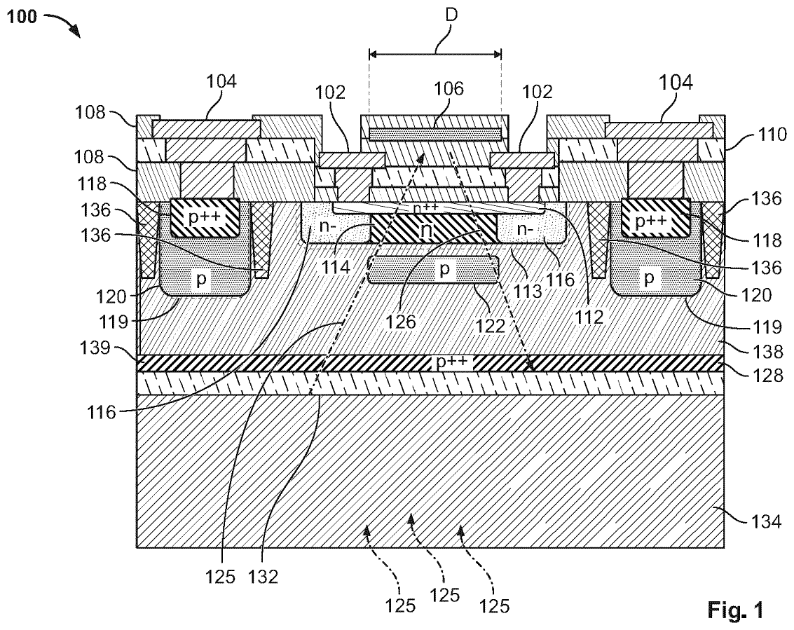

FIG. 1 shows the photosensitive element 100 according to the present disclosure. The photosensitive element 100 comprises a semiconductor substrate 138 with a first contact region 113 and a second contact region 119. The first contact region 113 comprises regions of different conductivity of a first conductivity type and the second contact region 119 comprises regions of different conductivity of a second conductivity type.

The first contact region 113 is connected to a first contact 102 and the second contact region 119 is connected to a second contact 104. In the embodiment shown in FIG. 1, the first contact 102 is described as the cathode and the second contact 104 is described as the anode of the photosensitive element 100. In the shown embodiment, the second contact 104 is disposed radially outwardly to the first contact 102. Further, the first contact 102 and the second contact 104 may comprise metal and/or metal alloy.

As shown in FIG. 1, the first contact region 113 comprises a highly doped first region 112 of the first conductivity type, which is disposed above a first well 114 of the first conductivity type. A second region 116 of the first conductivity type is disposed radially outwardly to the first region 112 and the first well 114. The second contact region 119 comprises a highly doped third region 118 of the second conductivity type disposed above a second well 120 of the second conductivity type.

In an embodiment, the first conductivity type is an n-type and the second conductivity type is a p-type. Further, the semiconductor substrate 138 is exemplarily chosen as a p-type substrate, which comprises silicon. Using a thin layer of silicon has the positive effect that the breakdown voltage can be reduced. Thus, in an example, the first contact region 113 comprises differently doped regions of an n-type and the second contact region 119 comprises differently doped regions of a p-type.

In the embodiment shown in FIG. 1, the second contact region 119 is at least partly surrounded by a trench 136. The trench 136 comprises a doped sidewall of the second conductivity type to advantageously increase the charge transfer efficiency. Thereby, the depth of a doped sidewall of the second conductivity type might increase with a depth of the trench 136. Alternatively, the doping concentration on the trench side walls is substantially uniform at different depths of the trench 136. The trench 136 provides a low path resistance to increase the charge collection efficiency and reduces potential dark noise sources.

As shown in FIG. 1, a third well 122 of the second conductivity type may be arranged below the first contact region 113 and is completely surrounded by the semiconductor substrate 138.

In an advantageous example of the present disclosure, the photosensitive element 100 is a linear mode avalanche photodiode (APD) that is fabricated on bipolar technology. The present disclosure is based on the idea that the sensitivity and speed of the APD also for radiation of long wavelengths can be increased by improving the structure of the APD. Fabricating the APD on bipolar technology overcomes the drawbacks of the standard CMOS technology, which has a restricted degree of freedom with respect to developing such a detector. This limitation originates from the impossibility of modifying a process flow that has to be optimized for a high performance transistor as well. Further advantages arising from fabricating the APD on bipolar technology are that design requirements as the size of an active area, the distance between the cathode and the anode, and the semiconductor substrate thickness are no longer limiting factors. Further, also the contact opening of the semiconductor substrate to deposit metal on it can be freely chosen. Using the bipolar technology advantageously also provides an APD with a low input impedance; at the same time, a high drive current, speed and gain can be realized.

Incident radiation 125 enters the photosensitive element 100 from a radiation receiving area 139, as shown in FIG. 1. This radiation receiving area 139 may be made from a metal-free material. When a voltage is applied between the first contact 102 and the second contact 104, a multiplication region is formed at the first contact region 113. The applied voltage enhances the electric field around the multiplication region. When incident radiation enters the photosensitive element, it gets absorbed and electron-hole pairs are generated. These charge carriers drift to the multiplication region where the high electric field exists and are multiplied there. When the velocity is the highest, the charge carriers will collide with other atoms and produce new electron-hole pairs. This results in a high photocurrent.

Due to the arrangement of the first contact 102 and the second contact 104 on one side of the photosensitive element 100, the charge that is created due to the incident radiation 125 flows laterally through the photosensitive element 100.

FIG. 1 also shows that either an anti-reflective coating (ARC) or a Bragg filter 132 is arranged below the semiconductor substrate 138. The term “below” denotes a relative term meaning that the ARC or the Bragg filter 132 are arranged at the radiation receiving area 139 of the photosensitive element 100 and are hit by the incident radiation 125 before entering the semiconductor substrate 138. The anti-reflective coating 132 improves the radiation transmission properties of the radiation receiving area.

In an embodiment, between the ARC/the Bragg filter 132 and the semiconductor substrate 138, a highly doped fourth region 128 of the second conductivity type is arranged. The fourth region 128 reduces the contribution of trapped charges or defects point at the side of the photosensitive element where the radiation enters.

As shown in FIG. 1, below the ARC or below the Bragg filter 132 a glass wafer 134 is placed. The glass wafer 134 is used as the handling component to case the processing of the photosensitive element 100. The glass wafer 134 is removed after the bonding process. Thus, the incident radiation 125 first enters the ARC or the Bragg filter 132, then the fourth region 128, and the semiconductor substrate 138.

The ARC as well as the Bragg filter improves the absorption characteristics at a desired wavelength and enables incident radiation to enter the substrate. The properties of the ARC can be advantageously chosen depending on the wavelength that is of interest.

Incident radiation 125 that has not been absorbed on the incoming path is reflected by a radiation reflecting area 106 that is disposed in the photosensitive element 100. This radiation reflecting area 106 is arranged on the side opposite to the radiation receiving area 139, as shown in FIG. 1. In the shown embodiment, the radiation reflecting area 106 is arranged on the same side of the photosensitive element 100 as the first contact 102 and the second contact 104. In the shown embodiment, the radiation reflecting area 106 is arranged substantially centered in the photosensitive element. The first contact 102 radially surrounds the radiation reflecting area 106. The second contact 104 in turn radially surrounds the first contact 102.

The incident radiation 125 is reflected by the radiation reflecting area 106 resulting in a reflected ray 126, shown in FIG. 1. Thus, the incident radiation 125 is substantially reflected back into the multiplication region and the semiconductor substrate 138, where it can be absorbed. The reflection of the incident radiation 125 doubles the effective distance the radiation entails in the photosensitive element. This advantageously increases the probability that the radiation, also referred to as light, will be absorbed in the substrate. This is of particular interest because electromagnetic energy has different absorption depths depending on its wavelength. Long wavelengths in the red and infrared range are absorbed deep in the substrate. When mirroring the incident ray, long wavelengths can be absorbed while at the same time the thickness of the substrate can advantageously be reduced. Reducing the thickness of the substrate advantageously improves the speed and the sensitivity of the photosensitive element.

In particular, the reflection of the incident radiation 125 enables that the depth of the semiconductor substrate 138 can be effectively reduced without having an impact on the radiation that can be absorbed. In an embodiment, the depth of the semiconductor substrate 138 is chosen to be less than the total absorption depth of wavelength in the red-infrared spectrum. The particularly short depth of the substrate reduces the package size of the photosensitive element. Thus, a particularly compact and small photosensitive element is obtained, which still absorbs long wavelengths.

Providing a photosensitive element with a comparable thin substrate and a radiation reflecting area improves both the speed and the sensitivity of the photosensitive element. The fabrication of the photosensitive element based on bipolar technology uses a silicon substrate, which advantageously makes the use of a thick epitaxial (EPI) layer unnecessary. This advantageously overcomes the drawback of previous solutions using the EPI layer that a trade-off between the sensitivity and the speed of the photosensitive element has to be found. Further, the thinned silicon substrate allows a low temperature coefficient and a low breakdown voltage of the photosensitive element, particularly in the near infrared spectral range.

A radiation reflecting area according to the present disclosure might be any area of different size that can be used to reflect a radiation of various wavelength. Thereby, the present invention is not limited to any certain specific reflective material, but might be any reflective material. The material that is used might be chosen depending on the radiation wavelength that is to be reflected, making the present invention applicable for a various number of applications.

The radiation receiving area may be made from a metal-free material.

In an embodiment, the radiation reflecting area 106 has a diameter D of 230 μm and comprises metal and/or metal alloy. Exemplarily, the radiation reflecting area 106 is made of aluminum.

With a photosensitive element 100 as presented, a peak sensitivity of between 70% and 80% (A/W) for a wavelength at a spectral range of 800 nm-930 nm can be reached. In an embodiment, a peak sensitivity of 73% (A/W) at a wavelength of 905 nm can be reached. Exemplarily, the sensitivity value can be reached with a thickness of the semiconductor substrate of 30 μm.

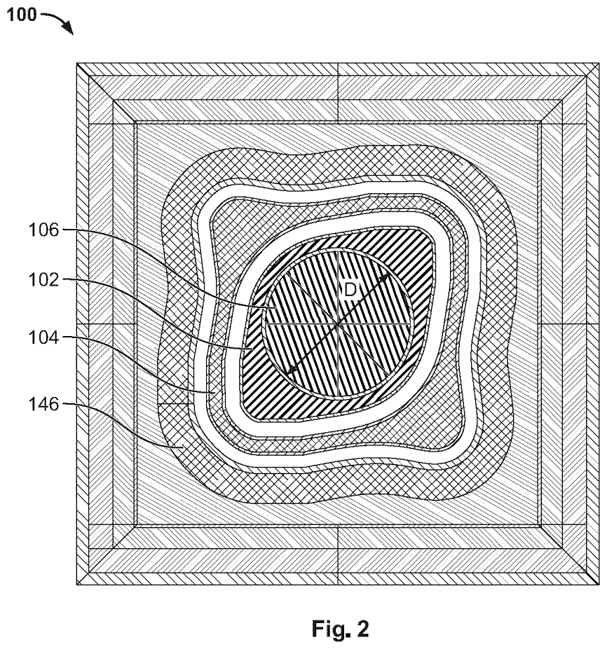

FIG. 2 shows a view on the layout of the photosensitive element 100. As can be seen, the radiation reflecting area 106, in the shown embodiment, is placed substantially centered having a diameter of 230 μm. The first contact 102 is positioned radially outwardly thereto. The second contact 104 is placed radially outwardly to the first contact 102 and is electrically separated from the first contact 102. In the embodiment shown in FIG. 2, radially outwardly to the second contact 104, a channel stopper 146 is arranged.

As shown in FIG. 1, the first contact 102 and the second contact 104 are exemplarily electrically separated via a layer 108 that comprises oxide. Exemplarily, multiple layers 108 are separated by a layer 110 comprising nitride.

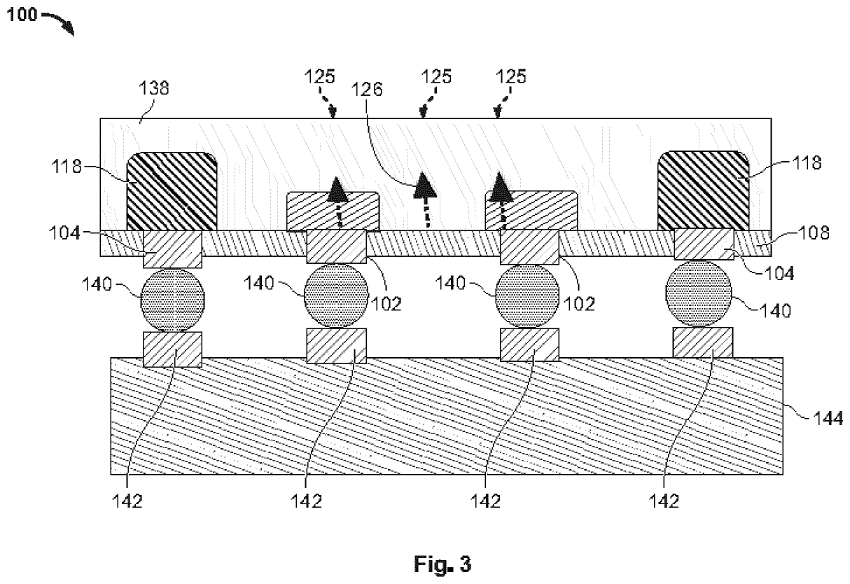

FIG. 3 shows the photosensitive element 100 assembled onto a carrier 144. This Figure emphasizes certain features of the present photosensitive element 100. Having the first contact 102 and the second contact 104 arranged on the same side of the photosensitive element 100, enables it to bond these contacts via flip-chip bonding. Flip-chip bonding is a very reliable and easy-to-integrate bonding method. Via bonding components 140 each contact 102, 104 is bonded with respective bonding parts 142 of the carrier 144. Thereby, the carrier 144 is particularly arranged on the side opposite to the radiation receiving area 139 of the photosensitive element 100.

The present invention further relates to an assembly method providing the photosensitive element 100 according to a development of the present disclosure and further comprises the steps of: Assembling the photosensitive element 100 on the carrier 144, with the carrier 144 being arranged on the side opposite to the radiation receiving area 139 of the photosensitive element 100.

The advantageous structure of the photosensitive element enables that the element can be assembled on the carrier via flip-chip bonding. This assembly method improves the reliability and reduces the package size of the element. Further, the assembled photosensitive element can be easily integrated into existing solutions and further processed. Using a flip-chip bonding instead of the standard wire bonding assembly method also has advantageous effects on the signal-to-noise ratio (SNR) and the fill factor of the photosensitive element.

The present invention provides an improved photosensitive element with a reduced size and an improved sensitivity and speed in order to overcome the disadvantages of the conventional technologies.

What is claimed is:

1. A photosensitive element, comprising:
a semiconductor substrate having a radiation receiving area through which an incident radiation can enter the photosensitive element and a radiation reflecting area disposed on a side of the semiconductor substrate opposite the radiation receiving area;
a first contact region connected to a first contact; and
a second contact region connected to a second contact, a multiplication region multiplying a plurality of charges generated from the incident radiation is formed at the first contact region when a voltage is applied between the first contact and the second contact, the first contact and the second contact are arranged on the side of the semiconductor substrate opposite the radiation receiving area.

2. The photosensitive element of claim 1, wherein the first contact region has a plurality of first regions of different conductivity of a first conductivity type.

3. The photosensitive element of claim 2, wherein the second contact region has a plurality of second regions of different conductivity of a second conductivity type.

4. The photosensitive element of claim 3, wherein the first contact region has a highly doped first region of the first conductivity type disposed above a first well of the first conductivity type.

5. The photosensitive element of claim 4, wherein the first contact region has a second region of the first conductivity type disposed radially outwards to the highly doped first region and the first well.

6. The photosensitive element of claim 5, wherein the second contact region has a highly doped third region of the second conductivity type disposed above a second well of the second conductivity type.

7. The photosensitive element of claim 3, wherein the semiconductor substrate is a p-type substrate, the first conductivity type is an n-type, and the second conductivity type is a p-type.

8. The photosensitive element of claim 3, wherein the second contact region is at least partly surrounded by a trench.

9. The photosensitive element of claim 8, wherein the trench has a doped sidewall of the second conductivity type.

10. The photosensitive element of claim 1, wherein the radiation reflecting area has a diameter of 230 μm.

11. The photosensitive element of claim 2, wherein an anti-reflective coating or a Bragg filter is arranged below the semiconductor substrate at the radiation receiving area.

12. The photosensitive element of claim 11, wherein a highly doped fourth region of the second conductivity type is arranged between the semiconductor substrate and the anti-reflective coating or the Bragg filter.

13. The photosensitive element of claim 1, wherein the semiconductor substrate has silicon.

14. The photosensitive element of claim 1, wherein the photosensitive element is a linear mode avalanche photodiode fabricated on bipolar technology.

15. The photosensitive element of claim 1, wherein the radiation reflecting area has a metal and/or a metal alloy.

16. The photosensitive element of claim 1, wherein the semiconductor substrate has a depth that is less than a total absorption depth of wavelength in a red-infrared spectrum.

17. The photosensitive element of claim 3, wherein a third well of the second conductivity type is arranged below the first contact region.

18. The photosensitive element of claim 17, wherein the third well is completely surrounded by the semiconductor substrate.

19. The photosensitive element of claim 1, wherein the photosensitive element has a peak sensitivity of 73% (A/W) at a wavelength of 905 nm.

20. A method of assembling a photosensitive element, comprising:
providing the photosensitive element of claim 1; and
assembling the photosensitive element on a carrier, the carrier is on the side of the photosensitive element opposite the radiation receiving area.
